(19) United States
(12) Patent Application Publication
(10) Pub. No.: US 2014/0014976 A1
(43) Pub. Date: Jan. 16, 2014

(54) OPTICAL DEVICE AND PROCESSING METHOD OF THE SAME

(71) Applicant: Disco Corporation, Tokyo (JP)

(72) Inventors: Takashi OKAMURA, Tokyo (JP); Taro ARAKAWA, Tokyo (JP)

(21) Appl. No.: 13/937,976

(22) Filed: Jul. 9, 2013

(30) Foreign Application Priority Data
Jul. 11, 2012 (JP) 2012-155265

(51) Int. Cl. H01L 33/20

(52) U.S. Cl. CPC H01L 33/20
USPC 257/79; 438/33

(57) ABSTRACT

An optical device including: a rectangular front side having a light-emitting layer; a rectangular rear side parallel to the front side; and first to fourth lateral sides adapted to connect the front and rear sides, in which the first lateral side is inclined by a first angle with respect to a perpendicular of the front side, and the second lateral side opposed to the first lateral side is inclined by a second angle with respect to the perpendicular, and the third lateral side is inclined by a third angle with respect to the perpendicular, and the fourth lateral side opposed to the third lateral side is inclined by a fourth angle with respect to the perpendicular.

### BACKGROUND OF THE INVENTION

1. Field of the Invention

The present invention relates to an optical device and processing method of the same.

2. Description of the Related Art

In the manufacturing process of optical devices such as laser diodes (LDs) and light-emitting diodes (LEDs), optical device wafers are manufactured in which a light-emitting layer (epitaxial layer) having a plurality of optical devices is stacked on the top side of a substrate for crystal growth made of sapphire, SiC or other material, for example, by epitaxial growth. Individual optical device chips are manufactured by forming an optical device such as LD or LED in each of the areas partitioned by scheduled division lines in a grid pattern and dividing the optical device wafer into individual optical device chips along the scheduled division lines.

In the conventionally known method to divide an optical device wafer along scheduled division lines, laser-processed grooves are formed by irradiating a pulsed laser beam at a wavelength that can be absorbed by an optical device wafer along such scheduled division lines, after which the wafer is divided starting from the laser-processed grooves as division start points by applying an external force to the wafer (refer to Japanese Patent Laid-Open No. Hei 10-305420). In another method proposed to divide an optical device wafer, on the other hand, modified layers are formed inside the wafer by irradiating a pulsed laser beam at a wavelength that can transmit through the wafer onto focal points inside the wafer, after which an external force is applied to scheduled division lines whose strength has declined due to the modified layers, thus providing improved luminance of the optical device (refer, for example, to Japanese Patent Laid-Open No. 2008-006492).

### SUMMARY OF THE INVENTION

LEDs and other optical devices are required to Provide high luminance, resulting in a demand for improved light extraction efficiency. With the conventional processing method of an optical device, the laser beam strikes the wafer approximately perpendicularly, dividing an optical device wafer into individual device chips starting from laser-processed grooves or modified layers as division start points. Therefore, the lateral sides of each divided chip are processed to be approximately perpendicular relative to the light-emitting layer formed on the front side, causing the optical device to be in the shape of a rectangular parallelepiped. As a result, a large proportion of light emitted from the light-emitting layer is totally reflected by the lateral sides. Eventually, a large percentage of such light goes out within the optical device chip after repeated total reflection.

In light of the foregoing, it is an object of the present invention to provide an optical device and processing method of the same capable of offering improved light extraction efficiency.

In accordance with an aspect of the present invention, there is provided an optical device that has a front side, rear side and first to fourth lateral sides. The front side is rectangular and has a light-emitting layer. The rear side is rectangular and parallel to the front side. The first to fourth lateral sides connect the front and rear sides. The first lateral side is inclined by a first angle with respect to a perpendicular of the front side. The second lateral side opposed to the first lateral side is inclined by a second angle with respect to the perpendicular. The third lateral side is inclined by a third angle with respect to the perpendicular. The fourth lateral side opposed to the third lateral side is inclined by a fourth angle with respect to the perpendicular.

It is preferred that the cross-sectional shape of the optical device from the front side to rear side should be parallelogrammic or trapezoidal. It is preferred that the first to second angles should be all the same.

In accordance with another aspect of the present invention, there is provided a processing method of an optical device that has a front side, rear side and first to fourth lateral sides. The front side is rectangular and has a light-emitting layer. The rear side is rectangular and parallel to the front side. The first to fourth lateral sides connect the front and rear sides. The first lateral side is inclined by a first angle with respect to a perpendicular of the front side. The second lateral side opposed to the first lateral side is inclined by a second angle with respect to the perpendicular. The third lateral side is inclined by a third angle with respect to the perpendicular. The fourth lateral side opposed to the third lateral side is inclined by a fourth angle with respect to the perpendicular. The processing method includes a wafer preparation step, inclined plane setup step and laser processing step. The wafer preparation step prepares an optical device wafer that has a light-emitting layer on the front side and has an optical device in each of the areas of the light-emitting layer partitioned by a plurality of scheduled division lines that intersect each other. The inclined plane setup step sets up a plurality of inclined planes for the first to fourth lateral sides in the optical device wafer. The laser processing step forms, after performing the inclined plane setup step, laser processed grooves along the inclined planes by irradiating a pulsed laser beam at a wavelength that can be absorbed by the optical device wafer along the inclined planes.

It is preferred that the processing method of an optical device further includes a division step adapted to divide an optical device wafer into individual optical devices by applying an external force to the optical device wafer after performing the laser processing step.

The first to fourth lateral sides of the present optical device are inclined respectively by the first to fourth angles from the perpendicular with respect to the light-emitting layer, thus making it possible to reduce the amount of light totally reflected by the lateral sides of the optical device and contributing to improved light extraction efficiency.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of the front side of an optical device wafer;

FIG. 2 is a cross-sectional view of the optical device wafer describing an inclined plane setup step;

FIG. 3 is a perspective view illustrating an optical device wafer holding step;

FIG. 4 is a perspective view describing a laser processing step;

FIG. 5 is a block diagram of a laser beam irradiation unit;

FIG. 6 is a cross-sectional view of the optical device wafer illustrating the laser processing step;

FIG. 7 is a cross-sectional view of the optical device wafer illustrating a division step;

FIGS. 8A to 8C are cross-sectional views of the optical device wafer illustrating a modified layer formation step;

FIG. 9 is a cross-sectional view of the optical device wafer illustrating the division step;

FIG. 10 is a perspective view of an optical device according to a first embodiment of the present invention;

FIG. 11A is a cross-sectional view along line 11A to 11A in FIG. 10;

FIG. 11B is a cross-sectional view along line 11B to 11B in FIG. 10;

FIG. 12 is a perspective view of the optical device according to a second embodiment of the present invention;

FIG. 13A is a cross-sectional view along line 13A to 13A in FIG. 12;

FIG. 13B is a cross-sectional view along line 13B to 13B in FIG. 12;

FIG. 14A is a cross-sectional view along a first cutting line of an inverted trapezoidal optical device;

FIG. 14B is a cross-sectional view along a second cutting line orthogonal to the first cutting line; and

FIG. 15 is a cross-sectional view of the optical device according to still another embodiment.

### DETAILED DESCRIPTION OF THE PREFERRED EMBODIMENTS

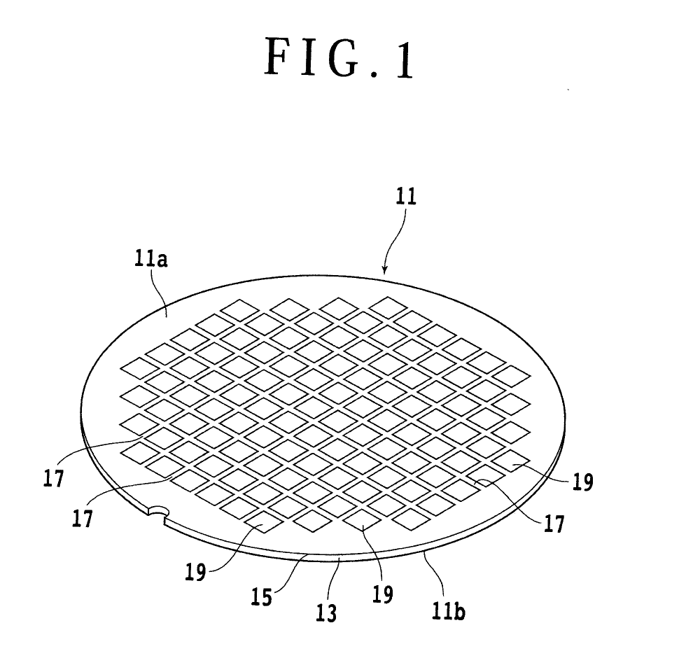

A detailed description will be given below of the preferred embodiments of the present invention with reference to the accompanying drawings. Referring to FIG. 1, a perspective view of the front side of an optical device wafer 11 is shown. The same wafer 11 includes a light-emitting layer (epitaxial layer) 15 made, for example, of gallium nitride (GaN) stacked on a sapphire substrate 13. The optical device wafer 11 has a front side 11a and rear side 11b. The light-emitting layer 15 is stacked on the front side 11a. The sapphire substrate 13 is exposed on the rear side 11b. The same substrate 13 is, for example, 100 μm in thickness, and the light-emitting layer is, for example, 5 μm in thickness. A plurality of optical devices 19 such as LEDs in a grid pattern, partitioned by a plurality of scheduled division lines (streets) 17, are formed in the light-emitting layer 15.

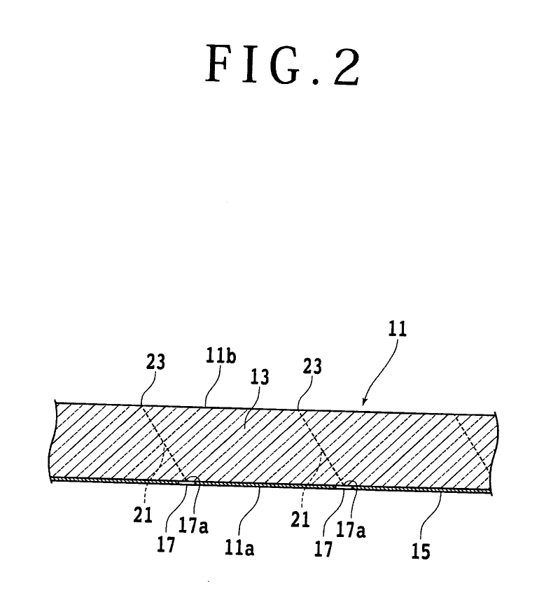

In the processing method of an optical device according to the present invention, the optical device wafer 11 as described above is prepared first, followed by an inclined plane setup step adapted to set up, in the optical device wafer 11, a plurality of inclined planes for the inclination angles of the lateral sides of the optical device to be formed. The inclined plane setup step sets up, based on the inclination angle of the lateral side of the optical device 19 to be formed and the thickness of the optical device wafer 11, intersection positions 23 as a laser beam irradiation line, each between one of inclined planes 21 having a predetermined angle and the rear side 11b when the inclined planes 21 are drawn from a center 17a of each of the scheduled division lines 17 to the rear side 11b as illustrated in FIG. 2.

Then, the deviation of the laser beam irradiation line from the center 17a of each of the scheduled division lines 17 in the direction of extension of the scheduled division lines 17 is calculated. It should be noted that the distance of this deviation will be hereinafter referred to as the offset distance. The offset distance is stored in the memory of a laser processing device 8 together with the center-to-center distance of the scheduled division lines 17 of the optical device wafer 11 (indexing amount).

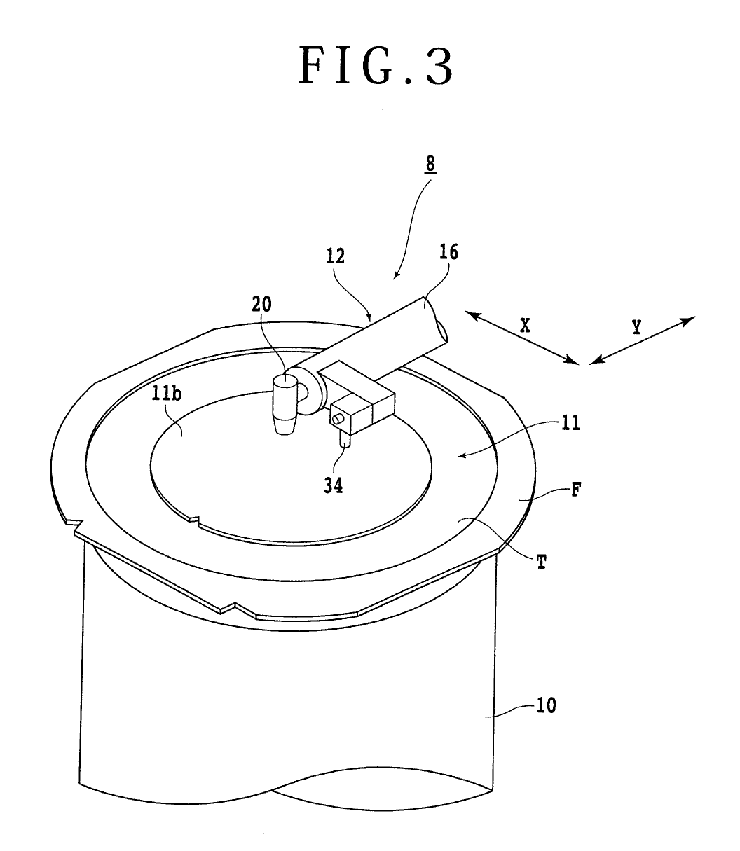

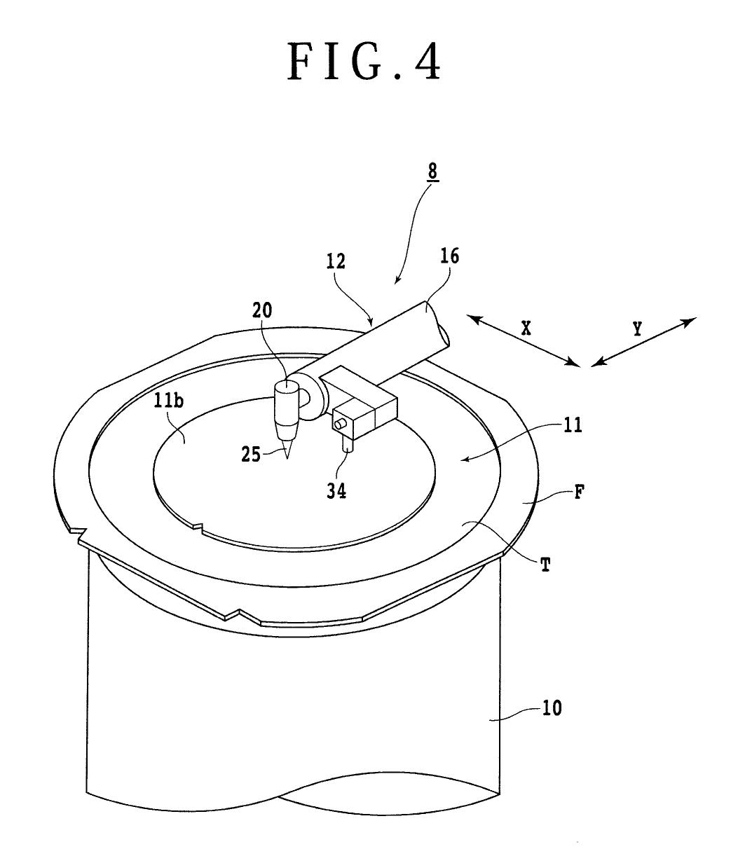

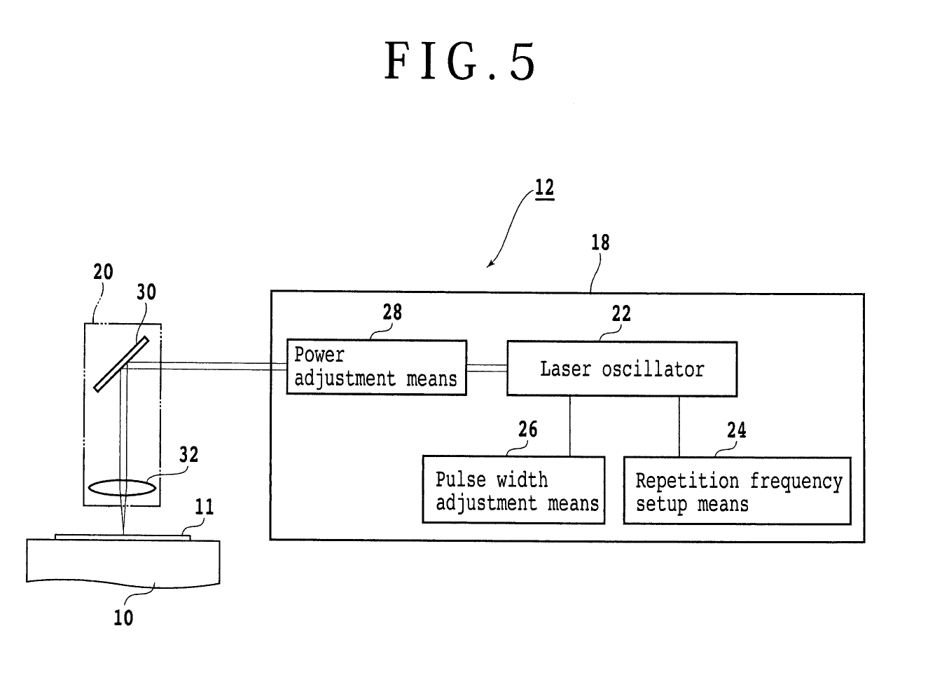

After the inclined plane setup step, the optical device wafer 11 is sucked and held by a chuck table 10 of the laser processing device 8 via a dicing tape T as illustrated in FIG. 3, thus exposing the rear side 11b of the optical device wafer 11. Then, an annular frame F to which the outer perimeter portion of the dicing tape T is affixed is clamped by a clamp which is not shown, thus fastening the annular frame F. A laser beam irradiation unit 12 includes a laser beam generation unit 18 and focusing unit (laser head) 20. The laser beam generation unit 18 is housed in a casing 16 shown in FIG. 5. The focusing unit 20 is rotatably attached to the tip portion of the casing 16.

Reference numeral 34 represents an imaging unit having not only a microscope and an ordinary imaging element such as CCD camera but also an infrared imaging element. The optical device wafer 11 includes the light-emitting layer 15 stacked on the sapphire substrate 13. Because of the transparence of the sapphire substrate 13, it is possible to image the scheduled division lines 17 formed on the front side 11a of the optical device wafer 11 with the normal imaging element from the rear side 11b thereof.

The processing method of an optical device according to the present invention performs alignment adapted to image the optical device wafer 11 with the imaging unit 34 from the rear side 11b and align the scheduled division lines 17 and focusing unit (laser head) 20 in the X-axis direction. In this alignment step, the scheduled division lines 17 of the optical device wafer 11 and the focusing unit 20 of the laser processing device 8 are aligned in the X-axis direction, thus detecting the same lines 17 extending in a first direction and storing the Y-axis coordinates thereof in the memory. Then, the chuck table 10 is rotated 90 degrees, followed by the detection of the scheduled division lines 17 extending in a second direction orthogonal to the first direction and the storage of the Y-axis coordinates thereof in the memory.

After the alignment, a laser beam at a wavelength that can be absorbed by the optical device wafer 11 is irradiated along the laser beam irradiation line on the rear side 11b of the wafer and by following an inclined plane 21, thus performing the laser processing step adapted to form a laser-processed groove 27. The same line 23 is at the offset distance from the scheduled division line 17.

The laser beam generation unit 18 of the laser beam irradiation unit 12 includes a laser oscillator 22, repetition frequency setup means 24, pulse width adjustment means 26 and power adjustment means 28 as illustrated in FIG. 5. The laser oscillator 22 oscillates a YAG or YVO4 laser. A pulsed laser beam adjusted to a given power level by the power adjustment means 28 of the laser beam generation unit 18 is reflected by a mirror 30 of the focusing unit 20 rotatably attached to the tip of the casing 16. The pulsed laser beam is further focused by a focusing objective lens 32, thus being irradiated onto the optical device wafer 11 held by the chuck table 10.

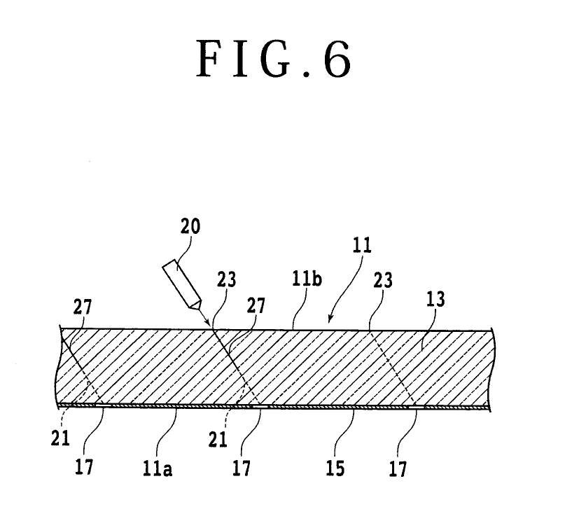

At the time of the laser processing step, the focusing unit 20 is rotated until it is parallel to the inclined plane 21 as illustrated in FIG. 6, after which a pulsed laser beam adjusted to a given power level is irradiated onto the rear side 11b of the optical device wafer 11, thus forming the laser-processed groove 27 of a given depth along each of the inclined planes 21. The laser-processed groove 27 is formed along each of the inclined planes 21 for all the scheduled division lines 17 extending in the first direction while at the same time indexing, by an indexing amount, the chuck table 10 in the Y-axis direction. Next, the chuck table 10 is rotated 90 degrees first, and then the laser-processed groove 27 is formed along each of the inclined planes 21 for all the scheduled division lines 17 extending in the second direction orthogonal to the first direction.

The processing conditions of this laser processing step are specified, for example, as follows:

Light source: LD pumped Q switch Nd: YAG laser
Wavelength: 355 nm (third harmonic generation of YAG laser)
Mean output: 2 W
Processing feed rate: 100 mm/second

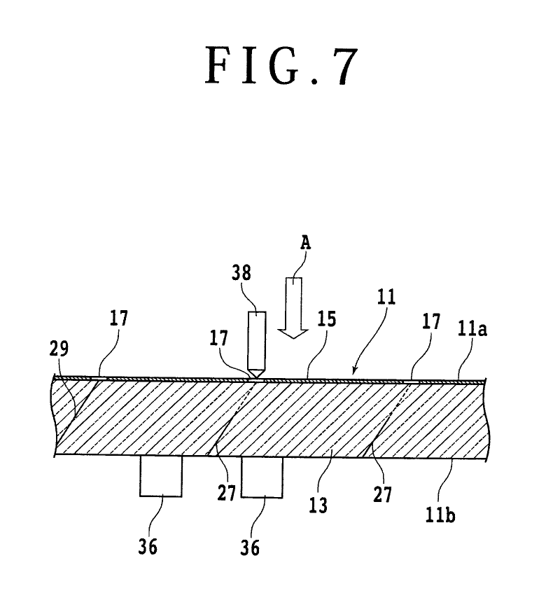

After the laser processing step, the division step is performed which is adapted to divide the optical device wafer 11 into individual optical devices by applying an external force to the same wafer 11. In the division step, the optical device wafer 11 is mounted to a pair of support beds 36 as illustrated, for example, in FIG. 7, with the rear side 11b thereof on the support beds 36 that are separated from each other by a given spacing so that the inclined laser-processed groove 27 is located between the support beds 36. Then, a wedge-shaped division bar 38 having a tip portion with an acute angle is moved in the direction indicated by an arrow A and pressed against the scheduled division line 17 formed on the front side 11a of the optical device wafer 11, thus dividing the same wafer 11 starting from the laser-processed groove 27 as a division start point in the manner shown by reference numeral 29. The division bar 38 is driven, for example, by an air cylinder.

When the division along the first laser-processed groove 27 is complete, the optical device wafer 11 is moved horizontally by a single pitch so that the next laser-processed groove 27 is positioned at the center between the pair of support beds 36. Then, the division bar 38 is driven, thus dividing the optical device wafer 11 starting from the next laser-processed groove 27 as a division start point. When the division along all the scheduled division lines 17 extending in the first direction is complete, the optical device wafer 11 is rotated 90 degrees, similarly dividing the same wafer 11 along the scheduled division lines 17 extending in the second direction orthogonal to the first direction. This allows the optical device wafer 11 to be divided into individual optical device chips. Although, in the description given above, the pair of support beds 36 and the division bar 38 are horizontally fixed whereas the optical device wafer 11 moves horizontally, the same wafer 11 may be maintained at standstill whereas the support beds 36 and division bar 38 may be moved horizontally one pitch at a time.

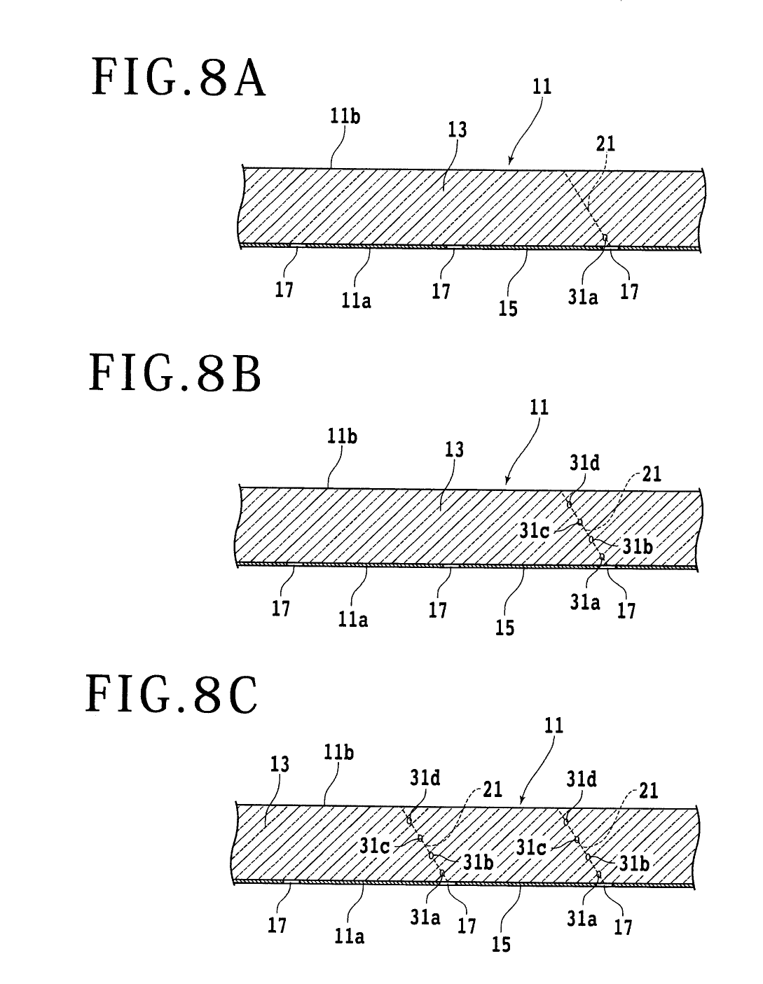

A description will be given next of the modified layer formation step, a laser processing step according to a second embodiment of the present invention, with reference to FIGS. 8A to 8C. In the modified layer formation step, the focal point of the laser beam is positioned near the front side 11a on the inclined plane 21 first as illustrated in FIG. 8A. Then, a laser beam at a wavelength that can transmit through the optical device wafer 11 is irradiated from the rear side 11b of the same wafer 11 onto a point at a given distance in the Y-axis direction from the scheduled division line 17 extending in the first direction, thus forming a first modified layer 31a inside the optical device wafer 11. Next, the focal point of the laser beam is moved gradually toward the rear side 11b, thus forming second, third and fourth modified layers 31b, 31c and 31d along the inclined plane 21 as illustrated in FIG. 8B. Next, the chuck table 10 is indexed by one pitch in the Y-axis direction, thus forming the similar first to fourth modified layers 31a to 31d along the inclined plane 21 for the next scheduled division line 17 as illustrated in FIG. 8C.

The laser processing conditions for forming the modified layers are specified, for example, as follows:

Light source: LD pumped Q switch Nd: YAG laser

### Wavelength: 1064 nm

Mean output: 0.1 to 0.2 W
Processing feed rate: 600 mm/second

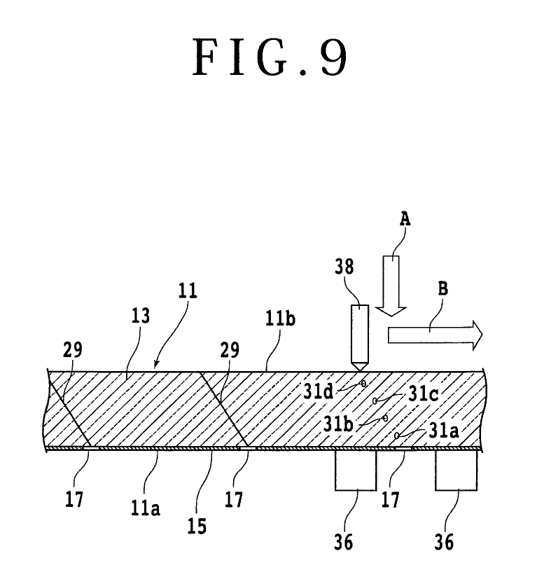

After performing the modified layer formation step along the inclined planes 21 for all the scheduled division lines 17, the optical device wafer 11 is mounted to the support beds 36 so that the first modified layer 31a is located between the pair of support beds 36 that are separated from each other by a given spacing as illustrated in FIG. 9. Then, the wedge-shaped division bar 38 having a tip portion with an acute angle is moved in the direction indicated by the arrow A and pressed against the rear side 11b of the optical device wafer 11, thus dividing the same wafer 11 starting from the modified layers 31a to 31d as division start points in the manner shown by reference numeral 29.

When the division along the inclined plane 21 having the modified layers 31a to 31d is complete, the optical device wafer 11 is moved by one pitch in the direction indicated by an arrow B so that the next first modified layer 31a is positioned at the center between the pair of support beds 36. Then, the division bar 38 is driven, thus dividing the optical device wafer 11 starting from the next modified layers 31a to 31d as division start points.

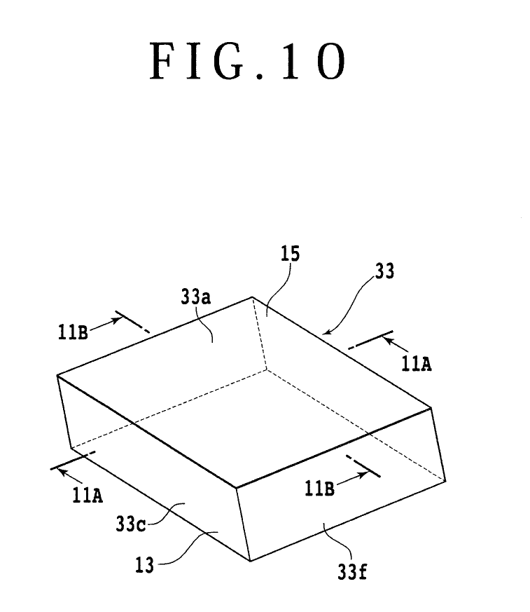

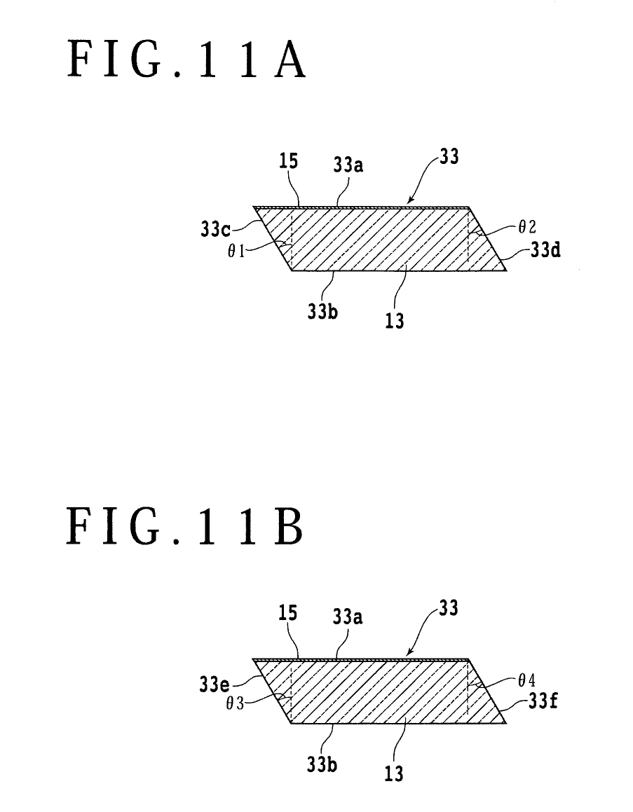

Referring to FIG. 10, a perspective view of an optical device 33 such as LED according to the first embodiment is shown which is formed by the processing method of an optical device according to the embodiments described above. The optical device 33 includes the light-emitting layer 15 stacked on the sapphire substrate 13. FIG. 11A is a cross-sectional view along line 11A to 11A in FIG. 10. FIG. 11B is a cross-sectional view along line 11B to 11B in FIG. 10.

The optical device 33 has a front side 33a, rear side 33b and first to fourth lateral sides 33c to 33f. The front side 33a is rectangular and has a light-emitting layer 15. The rear side 33b is rectangular with the sapphire substrate 13 exposed thereon. The first to fourth lateral sides 33c to 33f connect the front and rear sides 33a and 33b. The rear side 33b is approximately parallel to the front side 33a. As illustrated in FIG. 11A, the first lateral side 33c is inclined by a first angle θ1 with respect to the perpendicular of the front side 33a. The second lateral side 33d opposed to the first lateral side 33c is inclined by a second angle θ2 with respect to the perpendicular of the front side 33a. Further, as illustrated in FIG. 11B, the third lateral side 33e is inclined by a third angle θ3 with respect to the perpendicular of the front side 33a. The fourth lateral side 33f opposed to the third lateral side 33e is inclined by a fourth angle θ4 with respect to the perpendicular of the front side 33a.

For example, the first to fourth angles θ1 to θ4 of the optical device 33 according to the present embodiment are all the same. In this case, the cross-sectional shape (vertical cross-sectional shape) of the optical device 33 from the front side 33a to rear side 33b is parallelogrammic. For example, θ1 to θ4 are 30 degrees. Also, θ1 to θ4 may be different angles from one another.

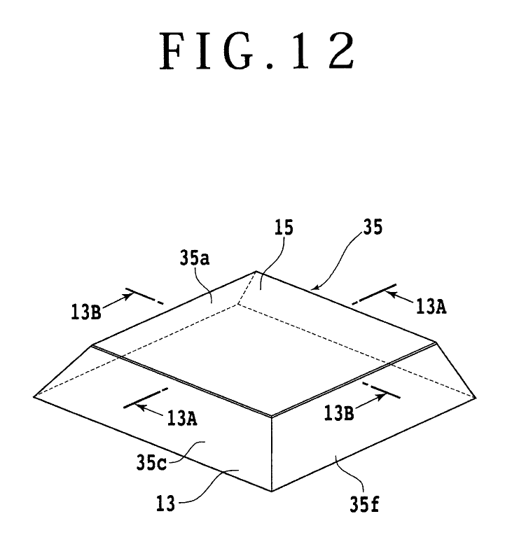

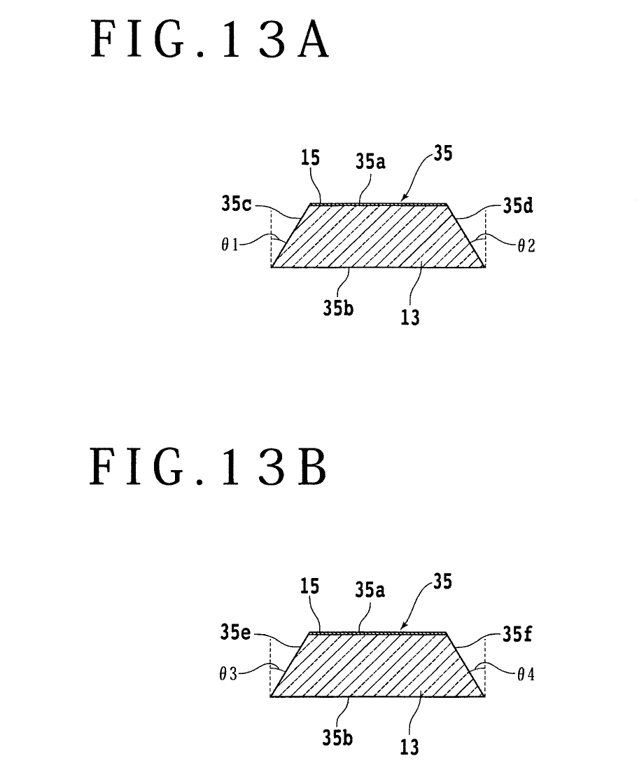

Referring to FIG. 12, a perspective view of an optical device 35 according to the second embodiment of the present invention is shown. FIG. 13A is a cross-sectional view along line 13A to 13A in FIG. 12. FIG. 13B is a cross-sectional view along line 13B to 13B in FIG. 12. The optical device 35 has a front side 35a, rear side 35b and first to fourth lateral sides 35c to 35f. The front side 35a is rectangular and has a light-emitting layer 15. The rear side 35b is rectangular and formed to be approximately parallel to the front side 35a with the sapphire substrate 13 exposed thereon. The first to fourth lateral sides 35c to 35f connect the front and rear sides 35a and 35b.

As illustrated in FIG. 13A, the first lateral side 35c is inclined by the first angle θ1 with respect to the perpendicular of the front side 35a. The second lateral side 35d opposed to the first lateral side 35c is inclined by the second angle θ2 with respect to the perpendicular of the front side 35a. Further, as illustrated in FIG. 13B, the third lateral side 35e is inclined by the third angle 93 with respect to the perpendicular of the front side 35a. The fourth lateral side 35f opposed to the third lateral side 35e is inclined by the fourth angle θ4 with respect to the perpendicular of the front side 35a.

Here, if the first to fourth angles θ1 to θ4 are all the same, the vertical cross-sectional shape (cross-sectional shape from the front side 35a to rear side 35b) of the optical device 35 is trapezoidal. The first to fourth angles θ1 to θ4 may be all different from one another.

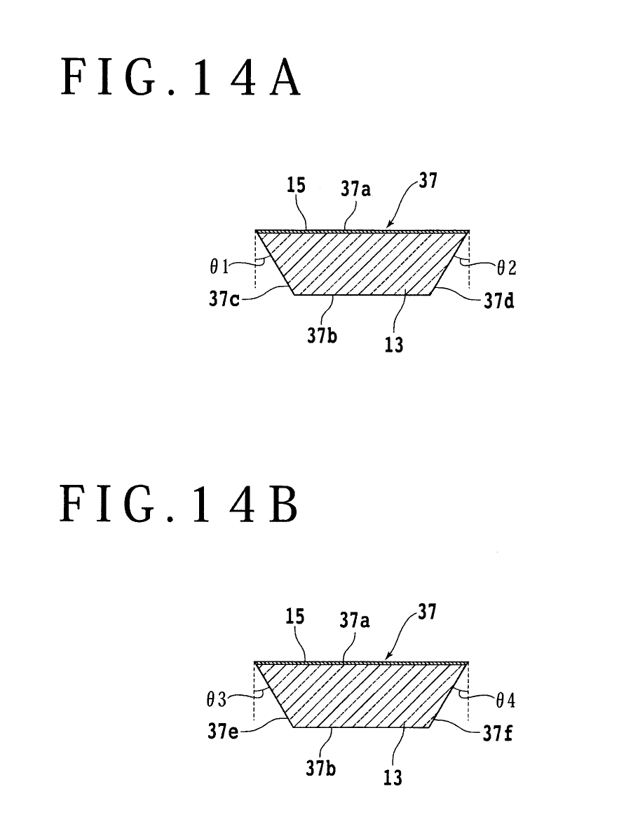

Referring to FIGS. 14A and 14B, a vertical cross-sectional view of an optical device 37 according to a third embodiment of the present invention is shown. The optical device 37 according to the present embodiment has a front side 37a, rear side 37b and first to fourth lateral sides 37c to 37f. The front side 37a is rectangular and has a light-emitting layer 15. The rear side 37b is rectangular and approximately parallel to the front side 37a with the sapphire substrate 13 exposed thereon. The first to fourth lateral sides 37c to 37f connect the front and rear sides 37a and 37b. As illustrated in FIG. 14A, the first lateral side 37c is inclined by the first angle θ1 with respect to the perpendicular of the front side 37a. The second lateral side 37d opposed to the first lateral side 37c is inclined by the second angle θ2 with respect to the perpendicular of the front side 37a. Further, as illustrated in FIG. 14B, the third lateral side 37e is inclined by the third angle θ3 with respect to the perpendicular of the front side 37a. The fourth lateral side 37f opposed to the third lateral side 37e is inclined by the fourth angle θ4 with respect to the perpendicular of the front side 37a.

If the first to fourth angles θ1 to θ4 are all the same, the vertical cross-sectional shape of the optical device 37 from the front side to rear side is inverted trapezoidal. Of course, the first to fourth angles θ1 to θ4 may be all different from one another.

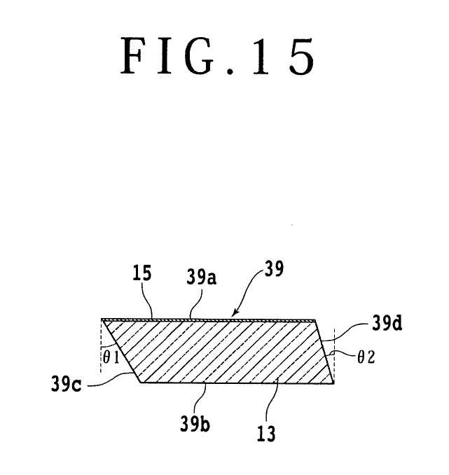

Referring to FIG. 15, a vertical cross-sectional view of an optical device 39 according to a fourth embodiment of the present invention is shown. The optical device 39 has a front side 39a, rear side 39b and four lateral sides. The front side 39a is rectangular and has a light-emitting layer 15. The rear side 39b is rectangular and approximately parallel to the front side 39a with the sapphire substrate 13 exposed thereon. The lateral sides connect the front and rear sides 39a and 39b.

As is clear from FIG. 15, a first lateral side 39c is inclined by the first angle θ1 with respect to the perpendicular of the front side 39a. A second lateral side 39d opposed to the first lateral side 39c is inclined by the second angle θ2 which is different from the first angle θ1 with respect to the perpendicular of the front side 39a. Although the third and fourth lateral sides are not shown, the third lateral side may be inclined by the third angle θ3, and the fourth lateral side may be inclined by the fourth angle θ4 which is different from the third angle θ3.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An optical device comprising:
a rectangular front side having a light-emitting layer;
a rectangular rear side parallel to the front side; and
first to fourth lateral sides adapted to connect the front and rear sides, wherein
the first lateral side is inclined by a first angle with respect to a perpendicular of the front side, and the second lateral side opposed to the first lateral side is inclined by a second angle with respect to the perpendicular, and the third lateral side is inclined by a third angle with respect to the perpendicular, and the fourth lateral side opposed to the third lateral side is inclined by a fourth angle with respect to the perpendicular.

2. The optical device of claim 1, wherein
the cross-sectional shape from the front side to rear side is parallelogrammic.

3. The optical device of claim 1, wherein
the cross-sectional shape from the front side to rear side is trapezoidal.

4. The optical device of claim 1, wherein
the first to fourth angles are all the same.

5. A processing method of an optical device, the optical device including a rectangular front side having a light-emitting layer, a rectangular rear side parallel to the front side, and first to fourth lateral sides adapted to connect the front and rear sides, wherein the first lateral side is inclined by a first angle with respect to a perpendicular of the front side, and the second lateral side opposed to the first lateral side is inclined by a second angle with respect to the perpendicular, and the third lateral side is inclined by a third angle with respect to the perpendicular, and the fourth lateral side opposed to the third lateral side is inclined by a fourth angle with respect to the perpendicular,
the processing method comprising:
a wafer preparation step of preparing an optical device wafer that has a light-emitting layer on the front side and has an optical device in each of the areas of the light-emitting layer partitioned by a plurality of scheduled division lines that intersect each other;
an inclined plane setup step of setting up a plurality of inclined planes for the first to fourth lateral sides in the optical device wafer; and
a laser processing step of forming, after performing the inclined plane setup step, laser processed grooves along the inclined planes by irradiating a pulsed laser beam at a wavelength that can be absorbed by the optical device wafer along the inclined planes.

6. The processing method of an optical device of claim 5, further comprising
a division step of dividing an optical device wafer into individual optical devices by applying an external force to the optical device wafer after performing the laser processing step.
